(19) United States
(12) Patent Application Publication
(10) Pub. No.: US 2026/0076134 A1
(43) Pub. Date: Mar. 12, 2026

(54) SUBSTRATE PROCESSING APPARATUS AND SUBSTRATE PROCESSING METHOD

(71) Applicant: Kioxia Corporation, Tokyo (JP)

(72) Inventors: Tomoya IWASAKI, Yokkaichi Mie (JP); Shiguma KATO, Mie Mie (JP); Koichiro KAWANO, Kamakura Kanagawa (JP); Tomohiko SUGITA, Yokkaichi Mie (JP); Yamato ISHIDA, Matsusaka Mie (JP)

(21) Appl. No.: 19/066,388

(22) Filed: Feb. 28, 2025

(30) Foreign Application Priority Data
Sep. 10, 2024 (JP) 2024-156526

(51) Int. Cl. H01L 21/67

(52) U.S. Cl. CPC H10P 72/0421

(57) ABSTRACT

A substrate processing apparatus includes: a substrate holder configured to hold a substrate; a shower head including a first hollow portion, a first slit coupled to the first hollow portion and extending in a first direction, a second slit coupled to the first slit and extending in a second direction intersecting the first direction and a third direction intersecting the first and second directions, a third slit coupled to the second slit and extending in the first direction, and a plurality of first gas ejection holes coupled to the first hollow portion, the shower head facing the substrate holder; a pipe structure including a first pipe coupled to the third slit; and a gas supplier connected to the first pipe and configured to supply a gas to the substrate from the plurality of first gas ejection holes.

### CROSS-REFERENCE TO RELATED APPLICATION

This application is based upon and claims the benefit of priority from Japanese Patent Application No. 2024-156526, filed Sep. 10, 2024, the entire contents of which are incorporated herein by reference.

### FIELD

Embodiments described herein relate generally to a substrate processing apparatus and a substrate processing method.

### BACKGROUND

Chemical vapor deposition (CVD) is known as one of deposition methods of forming thin films. This method is a method of supplying a material gas containing components of a targeting thin film on a substrate and decomposing the material gas by energy or the like of heat or plasma to deposit a metal thin film or a compound thin film on the surface of the substrate. On the other hand, methods of processing materials using reactive gases, ions, or radicals are known. When the films are formed or processed, a substrate processing apparatus that includes a shower head is provided to uniformly supply a gas to a substrate is provided.

### DESCRIPTION OF THE DRAWINGS

FIG. 1 is a sectional view schematically illustrating an overall configuration of a substrate processing apparatus according to one embodiment.

FIG. 2 is a perspective view schematically illustrating an overall configuration of a shower head according to one embodiment.

FIG. 3 is a sectional view illustrating a configuration of the shower head according to one embodiment.

FIG. 4 is a sectional view illustrating a configuration of the shower head according to one embodiment.

FIG. 5 is a sectional view illustrating a configuration of the shower head according to one embodiment.

FIG. 6 is a sectional view illustrating a configuration of the shower head according to one embodiment.

FIG. 7 is a sectional view illustrating a configuration of the shower head according to one embodiment.

FIG. 8 is a sectional view illustrating a configuration of the shower head according to one embodiment.

FIG. 9 is a sectional view illustrating a configuration of the shower head according to one embodiment.

FIG. 10 is a sectional view illustrating a configuration of the shower head according to one embodiment.

FIG. 11 is a flowchart illustrating film forming steps according to one embodiment.

### DETAILED DESCRIPTION

Embodiments provide a substrate processing apparatus and a substrate processing method capable of improving gas replacement efficiency and gas uniformity inside a shower head.

In general, according to one embodiment, a substrate processing apparatus includes: a substrate holder configured to hold a substrate; a shower head including a first hollow portion, a first slit coupled to the first hollow portion and extending in a first direction, a second slit coupled to the first slit and extending in a second direction intersecting the first direction and a third direction intersecting the first and second directions, a third slit coupled to the second slit and extending in the first direction, and a plurality of first gas ejection holes coupled to the first hollow portion, the shower head facing the substrate holder; a pipe structure including a first pipe coupled to the third slit; and a gas supplier connected to the first pipe and configured to supply a gas to the substrate from the plurality of first gas ejection holes.

Hereinafter, a substrate processing apparatus according to the present embodiment will be described specifically with reference to the drawings. In the following description, elements with substantially the same functions and configurations are denoted by the same reference numerals or reference signs to which alphabets are suffixed, and will be described repeatedly only when necessary. In the following embodiments, apparatuses that embody technical concepts of the embodiments will be exemplified. Embodiments can be changed in various forms within the scope that does not deviate from the gist of the present disclosure. These embodiments are included within the scope of the claims and equivalents of the claims.

The drawings are schematically illustrated in terms of widths, thicknesses, shapes, and the like of units compared to actual forms to further clarify description, but are merely an example and do not limit interpretation of the present disclosure. In the present specification and each drawing, elements that have functions similar to those described in the previous drawings are given the same reference references and repeated description thereof will be omitted.

In the present specification, expressions such as “α includes A, B, or C” do not exclude cases where α includes combinations of A to C unless otherwise mentioned. Further, these expressions do not exclude cases where α includes other elements.

In the present specification, “horizontal” refers to a direction (XY direction) that is horizontal to a stage of a substrate processing apparatus, and “vertical” refers to a direction (Z direction) that is substantially perpendicular to the above horizontal direction.

The following embodiments can be combined.

In the following embodiments, while a semiconductor substrate such as a silicon wafer as a substrate is described as an example, the technique of the present disclosure can be applied to a substrate (for example, a glass substrate, a quartz substrate, or the like) other than a semiconductor substrate on which it is necessary to execute film forming or processing treatment.

### First Embodiment

### Substrate Processing Apparatus

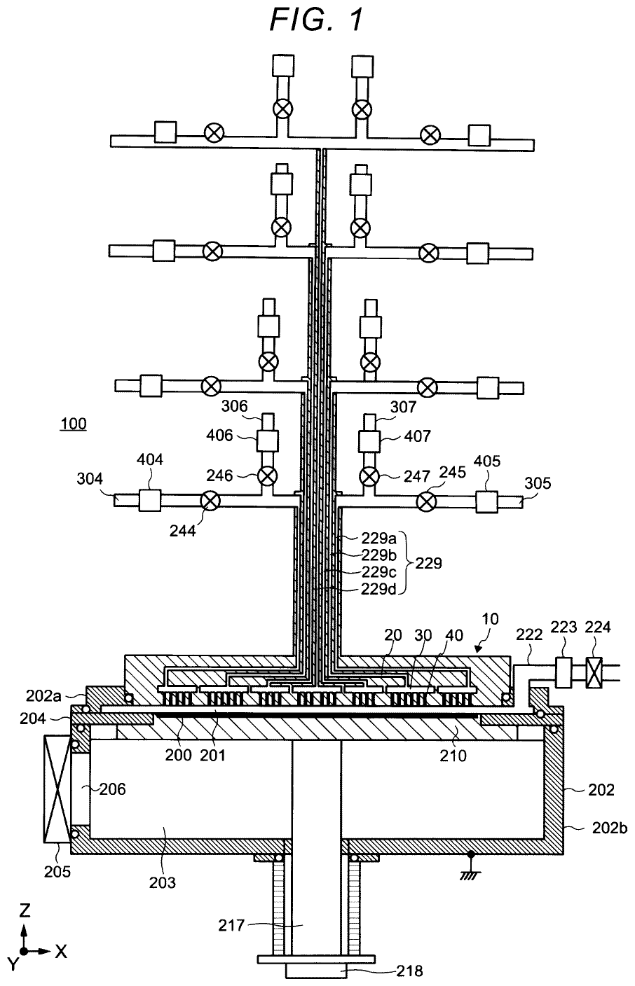

FIG. 1 is a sectional view schematically illustrating an overall configuration of a substrate processing apparatus according to one embodiment. A substrate processing apparatus 100 according to the present embodiment is, for example, a sheet-type substrate processing apparatus that executes film forming and processing treatment. The processing treatment includes, for example, a dry etching process. The surface of a semiconductor substrate is, for example, a surface on which a semiconductor device such as a 3-dimensional NAND is formed. For example, a circuit pattern (not illustrated) is formed on the surface of the semiconductor substrate.

As illustrated in FIG. 1, the substrate processing apparatus 100 includes a processing container 202. The processing container 202 is configured as, for example, a flat columnar airtight container. The processing container 202 is formed of, for example, a metal material such as aluminum (Al) or stainless steel (SUS). The processing container 202 includes an upper container 202a and a lower container 202b. A partition plate 204 is provided between the upper container 202a and the lower container 202b. A space surrounded by the upper container 202a and located above the partition plate 204 is referred to as a processing space 201, and a space surrounded by the lower container 202b and located below the partition plate 204 is referred to as a conveyance space 203.

A substrate conveyance-in/out port 206 adjacent to a gate valve 205 is provided on a side surface of the lower container 202b, and a wafer 200 is conveyed into or out from the conveyance space 203 via the substrate conveyance-in/out port 206.

In the processing space 201, a substrate holding unit (or substrate holder) 210 that supports the wafer 200 is provided. The substrate holding unit 210 holds the wafer 200. The substrate holding unit 210 has an upper surface that is circular in the XY direction, and one disk-shaped wafer 200 can be placed on the substrate holding unit 210 so that a principal surface is oriented in the horizontal direction (XY direction).

The substrate holding unit 210 is supported by a shaft 217. The shaft 217 is connected to a lifting mechanism 218. The substrate holding unit 210 and the shaft 217 are lifted up and down by the lifting mechanism 218, so that the wafer 200 placed on the substrate holding unit 210 can be lifted up or down. The substrate holding unit 210 is lifted down to the conveyance space 203 during conveyance of the wafer 200 and is lifted up to the processing space 201 during processing of the wafer 200.

An exhaust pipe 222 that evacuates the atmosphere of the processing space 201 is connected to an inner wall side surface of the processing space 201 (the upper container 202a). An auto pressure controller (APC) value 223 such as an APC controlling the inside of the processing space 201 to a predetermined pressure and a vacuum pump 224 are connected in order to the exhaust pipe 222.

A shower head 10 is provided above the processing space 201. The shower head 10 supplies any of various gases to be described below to the wafer 200 placed on the substrate holding unit 210. The lower surface of the shower head 10 faces the disk-shaped wafer 200 in parallel. A configuration of the shower head 10 will be described below.

A pipe unit (or pipe structure) 229 that supplies any of various gases into the processing space 201 is connected to the upper surface (ceiling wall) of the shower head 10. The pipe unit 229 includes a first pipe 229a, a second pipe 229b, a third pipe 229c, and a fourth pipe 229d. The second pipe 229b is disposed concentrically on the inner side of the first pipe 229a, the third pipe 229c is disposed concentrically on the inner side of the second pipe 229b, and the fourth pipe 229d is disposed concentrically on the inner side of the third pipe 229c, so that a quadruple pipe configuration is implemented.

Each of the first pipe 229a, the second pipe 229b, the third pipe 229c, and the fourth pipe 229d is connected to a gas supply unit (or gas supplier) that supplies any of various gases into the processing space 201. The gas supply unit includes, for example, a material gas supply pipe 304, a reactive gas supply pipe 305, a purge gas supply pipe 306, and a purge gas supply pipe 307.

For example, the material gas supply pipe 304 that supplies a material gas as a first processing gas is connected to the first pipe 229a. In the material gas supply pipe 304, a mass flow controller 404 serving as a flow rate controller that controls a supply flow rate of a gas and a valve 244 that controls supply of the gas are disposed from upstream. As the material gas, for example, a precursor gas such as TiCl₄ (titanium tetrachloride) gas is used.

For example, the reactive gas supply pipe 305 that supplies a reactive gas as a second processing gas is connected to the first pipe 229a. In the reactive gas supply pipe 305, a mass flow controller 405 and a valve 245 are disposed from upstream. As the reaction gas, for example, a gas with reducing properties such as an NH₃ (ammonia) gas is used.

For example, the purge gas supply pipe 306 that supplies an inert gas as a purge gas is connected to the material gas supply pipe 304 downstream of the valve 244. For example, the purge gas supply pipe 307 is connected to the reactive gas supply pipe 305 downstream of the valve 245. In the purge gas supply pipe 306 and the purge gas supply pipe 307, a mass flow controller 406, a mass flow controller 407, a valve 246, and a valve 247 are disposed from upstream. As the inert gas, for example, N₂ (nitrogen) gas is used. However, the embodiment is not limited thereto. As the purge gas, for example, a noble gas such as a helium (He) gas, a neon (Ne) gas, or an argon (Ar) gas can be used in addition to an N₂ gas.

Since configurations of gas supply units connected to the second pipe 229b, the third pipe 229c, and the fourth pipe 229d are similar to the configuration of the gas supply unit connected to the first pipe 229a, repeated description thereof will be omitted here. Types or flow rates of gasses supplied to the first pipe 229a, the second pipe 229b, the third pipe 229c, and the fourth pipe 229d may be the same or differ.

### Shower Head

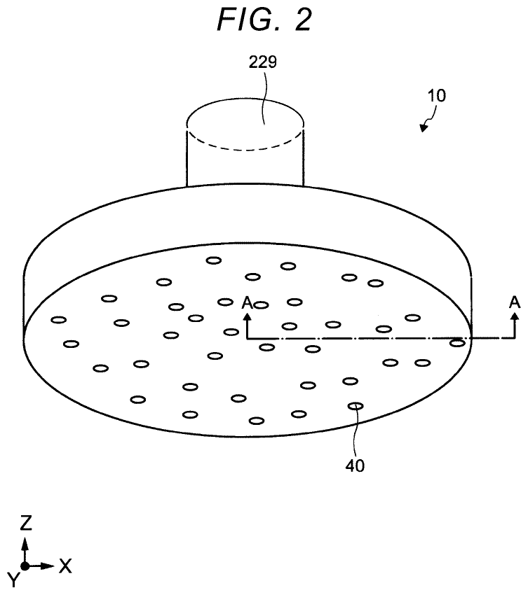

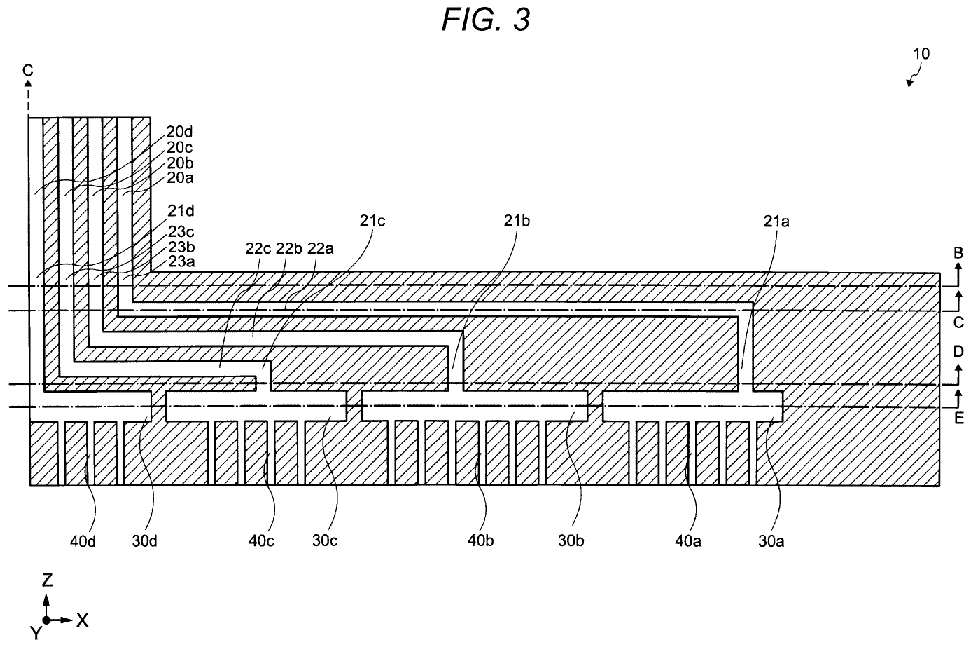

FIG. 2 is a perspective view schematically illustrating an overall configuration of a shower head according to one embodiment. FIG. 3 is an XZ sectional view illustrating a configuration of the shower head according to one embodiment. FIG. 3 is an enlarged sectional view illustrating the right half of the shower head at a location A of FIG. 2 and an overall configuration of the shower head that is a rotation body about a central axis C.

As illustrated in FIG. 2, the shower head 10 has, for example, a flat columnar shape, and the lower surface of the shower head 10 is circular in the XY direction. A plurality of gas ejection holes 40 are formed on the lower surface of the shower head 10. The pipe unit 229 is connected to the upper surface of the shower head 10.

In the shower head 10, slits 20, hollow portions 30, and the plurality of gas ejection holes 40 are provided (see FIG. 1). Any of various gases introduced from the pipe unit 229 connected to the gas supply unit is supplied to the wafer 200 placed on the substrate holding unit 210 via the slits 20, the hollow portions 30, and the plurality of gas ejection holes 40 of the shower head 10.

As illustrated in FIG. 3, a slit 20a connected to the first pipe 229a communicates with a hollow portion 30a, and the hollow portion 30a communicates with a plurality of gas ejection holes 40a. A slit 20b connected to the second pipe 229b communicates with a hollow portion 30b, and the hollow portion 30b communicates with a plurality of gas ejection holes 40b. A slit 20c connected to the third pipe 229c communicates with a hollow portion 30c, and the hollow portion 30c communicates with a plurality of gas ejection holes 40c. A slit 20d connected to the fourth pipe 229d communicates with a hollow portion 30d, and the hollow portion 30d communicates with a plurality of gas ejection holes 40d.

The slit 20a connecting the first pipe 229a to the hollow portion 30a includes a first slit 21a, a second slit 22a, and a third slit 23a. The first slit 21a communicates with the hollow portion 30a and extends in a first direction (Z direction). The second slit 22a communicates with the first slit 21a and extends in a second direction (X direction) intersecting the first direction (Z direction) and a third direction (Y direction) intersecting the first direction (Z direction) and the second direction (X direction). The third slit 23a communicates with the second slit 22a and extends in the first direction (Z direction). The third slit 23a communicates with the first pipe 229a.

The slit 20b connecting the second pipe 229b to the hollow portion 30b includes a first slit 21b, a second slit 22b, and a third slit 23b. The first slit 21b communicates with the hollow portion 30b and extends in the first direction (Z direction). The second slit 22b communicates with the first slit 21b and extends in the second direction (X direction) and the third direction (Y direction). The third slit 23b communicates with the second slit 22b and extends in the first direction (Z direction). The third slit 23b communicates with the second pipe 229b.

The slit 20c connecting the third pipe 229c to the hollow portion 30c includes a first slit 21c, a second slit 22c, and a third slit 23c. The first slit 21c communicates with the hollow portion 30c and extends in the first direction (Z direction). The second slit 22c communicates with the first slit 21c and extends in the second direction (X direction) and the third direction (Y direction). The third slit 23c communicates with the second slit 22c and extends in the first direction (Z direction). The third slit 23c communicates with the third pipe 229c.

The slit 20d connected to the fourth pipe 229d includes a first slit 21d. The first slit 21d extends in the first direction (Z direction) and communicates with the hollow portion 30d.

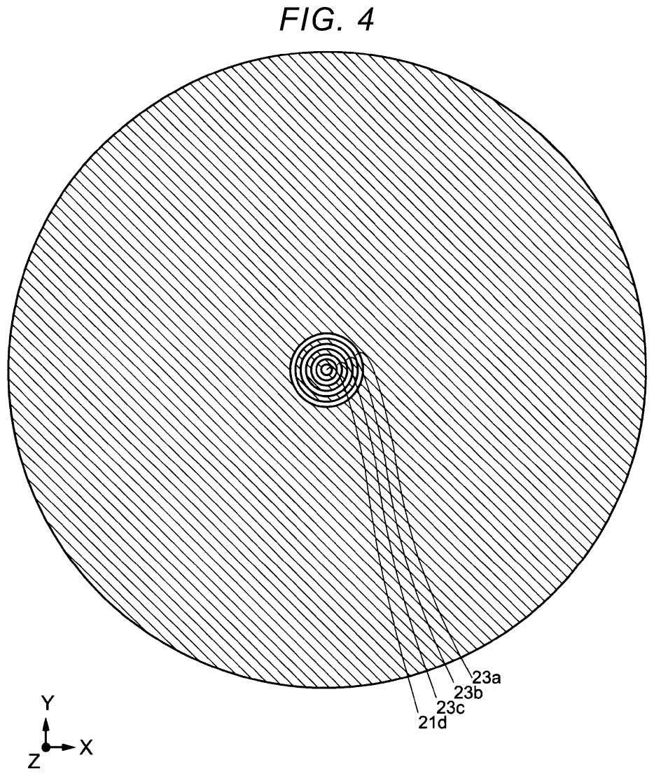

FIG. 4 is an XY sectional view illustrating a configuration of the shower head according to one embodiment. FIG. 4 is a sectional view illustrating the shower head at a location B of FIG. 3.

The third slit 23a, the third slit 23b, and the third slit 23c have a cylindrical shape and are disposed concentrically about the central axis C. The first slit 21d has a columnar shape and is disposed to centering on the central axis C. The third slit 23b is disposed inside the third slit 23a, the third slit 23c is disposed inside the third slit 23b, and the first slit 21d is disposed inside the third slit 23c, so that quadruple pipe configuration is implemented.

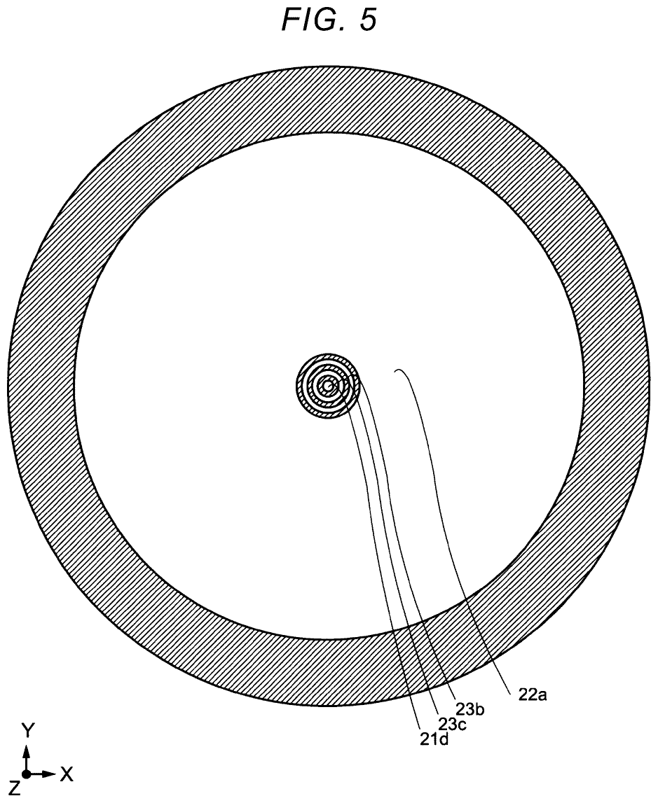

FIG. 5 is an XY sectional view illustrating a configuration of the shower head according to one embodiment. FIG. 5 is a sectional view illustrating the shower head at a location C of FIG. 3.

The second slit 22a, the second slit 22b, and the second slit 22c have a flat cylindrical shape (doughnut shape) and are disposed concentrically about the central axis C. The upper and lower surfaces of the second slit 22a, the second slit 22b, and the second slit 22c are disposed to be parallel. The second slit 22a, the second slit 22b, and the second slit 22c are disposed to be parallel in the Z direction. The second slit 22b is disposed below the second slit 22a, and the second slit 22c is disposed below the second slit 22b. The second slit 22a is larger than the second slit 22b in the XY direction, and the second slit 22b is larger than the second slit 22c in the XY direction.

The second slit 22a, the second slit 22b, and the second slit 22c according to the present embodiment are illustrated in the flat cylindrical shape (doughnut shape). However, the embodiment is not limited thereto. The second slit 22a, the second slit 22b, and the second slit 22c may have a conical cylindrical shape (triangular conic shape) in which a center is inclined upward.

The third slit 23b is disposed inside the second slit 22a, the third slit 23c is disposed inside the third slit 23b, and the first slit 21d is disposed inside the third slit 23c. The third slit 23c is disposed inside the second slit 22b, and the first slit 21d is disposed inside the third slit 23c. The first slit 21d is disposed inside the second slit 22c.

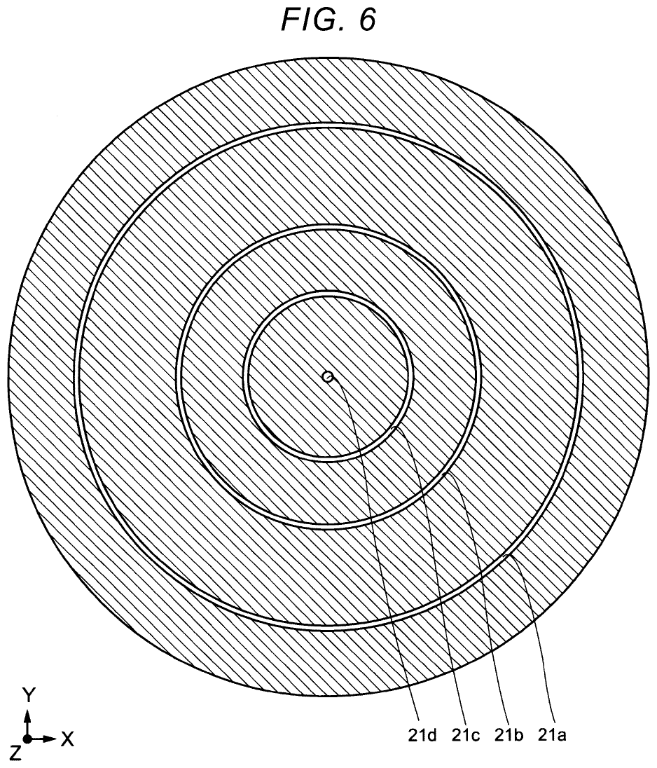

FIG. 6 is an XY sectional view illustrating a configuration of the shower head according to one embodiment. FIG. 6 is a sectional view illustrating the shower head at a location D of FIG. 3.

The first slit 21a, the first slit 21b, and the first slit 21c have a cylindrical shape and are disposed concentrically about the central axis C. The first slit 21d has a columnar shape and the central axis C is disposed at the center. The first slit 21b is disposed inside the first slit 21a, the first slit 21c is disposed inside the first slit 21b, and the first slit 21d is disposed inside the first slit 21c, so that a quadruple pipe configuration is implemented.

A width of the second slit 22a in the Z direction may be substantially the same as widths of the first slit 21a and the third slit 23a in the X direction. A width of the second slit 22b in the Z direction may be substantially the same as widths of the first slit 21b and the third slit 23b in the X direction. A width of the second slit 22c in the Z direction may be substantially the same as widths of the first slit 21c and the third slit 23c in the X direction.

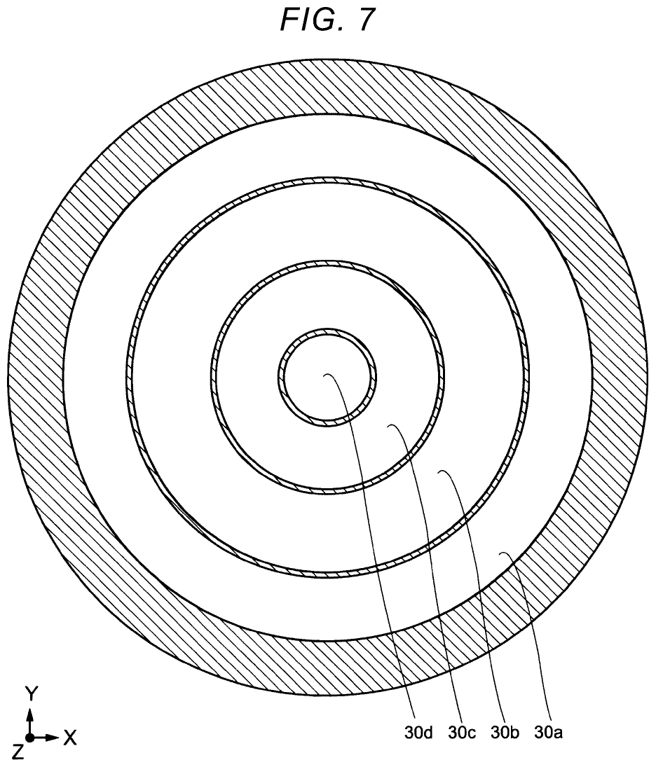

FIG. 7 is an XY sectional view illustrating a configuration of the shower head according to one embodiment. FIG. 7 is a sectional view illustrating the shower head at a location E of FIG. 3.

The hollow portion 30 temporarily stores any of various gases introduced from the pipe unit 229. Any of the various gases stored in the hollow portion 30 is ejected to the wafer 200 from the plurality of gas ejection holes 40 facing a processing region (principal surface) of the wafer 200 placed on the substrate holding unit 210.

The hollow portion 30 includes the hollow portions 30a, 30b, 30c, and 30d. The hollow portions 30a, 30b, and 30c have a flat cylindrical shape (doughnut shape) and are disposed concentrically about the central axis C. The hollow portion 30d has a flat columnar shape and is disposed concentrically about the central axis C. The upper and lower surfaces of the hollow portions 30a, 30b, 30c, and 30d are parallel and are disposed on the same XY surface. The hollow portion 30b is disposed inside the hollow portion 30a, the hollow portion 30c is disposed inside the hollow portion 30b, and the hollow portion 30d is disposed concentrically inside the hollow portion 30c, so that a quadruple pipe configuration is implemented. The hollow portions 30a, 30b, 30c, and 30d are disposed to correspond to a processing region (principal surface) of the wafer 200 placed on the substrate holding unit 210. It is preferable that an outer diameter of the hollow portion 30a be substantially the same as an outer diameter of the processing region (principal surface) of the wafer 200.

The plurality of gas ejection holes 40 include the plurality of gas ejection holes 40a, the plurality of gas ejection holes 40b, the plurality of gas ejection holes 40c, and the plurality of gas ejection holes 40d. The plurality of gas ejection holes 40a, the plurality of gas ejection holes 40b, the plurality of gas ejection holes 40c, and the plurality of gas ejection holes 40d each eject any of various gases stored in the hollow portions 30a, 30b, 30c, and 30d to the processing region (principal surface) of the wafer 200 placed on the substrate holding unit 210. The plurality of gas ejection holes 40a communicate with the hollow portion 30a and extend in the first direction (Z direction). The plurality of gas ejection holes 40b communicate with the hollow portion 30b and extend in the first direction (Z direction). The plurality of gas ejection holes 40c communicate with the hollow portion 30c and extend in the first direction (Z direction). The plurality of gas ejection holes 40d communicate with the hollow portion 30d and extend in the first direction (Z direction). The plurality of gas ejection holes 40 have the hole shape, as illustrated in FIG. 2. However, the embodiment is not limited thereto and the plurality of gas ejection holes 40 may have a columnar slit shape (doughnut shape) in a plan view.

The shower head 10 according to the present embodiment includes the plurality of hollow portions 30, and thus it is possible to control a flow rate of any of various gases ejected from the gas ejection holes 40. The shower head 10 according to the present embodiment has a configuration including four hollow portions 30. However, the embodiment is not limited thereto and the number of hollow portions 30 may be plural. When the number of hollow portions 30 is numerous, gas supply can be controlled more accurately, and thus it is possible to improve uniformity of the gas supplied in the processing region (principal surface) of the wafer 200.

In the shower head 10 according to the present embodiment, the pipe unit 229 and the plurality of hollow portions 30 are connected to the slits 20, and the upper and lower surfaces of the plurality of hollow portions 30 are disposed to be parallel to each other. Therefore, a volume of each flow passage system (the slit 20+the hollow portion 30+the gas ejection holes 40) inside the shower head 10 can be reduced, and thus it is possible to improve gas replacement efficiency and gas uniformity inside the shower head 10.

### Second Embodiment

### Shower Head

A configuration of a substrate processing apparatus according to the present embodiment is the same as the configuration of the substrate processing apparatus according to the first embodiment except for the configuration of the plurality of hollow portions. The same description as that of the first embodiment will be omitted. Here, differences from the configuration of the substrate processing apparatus according to the first embodiment will be described.

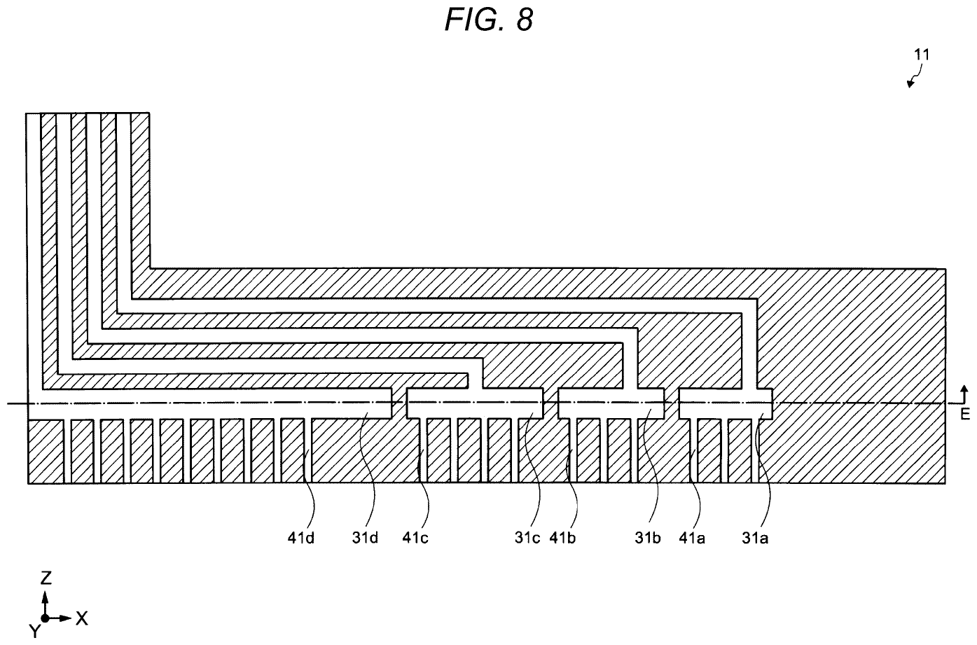

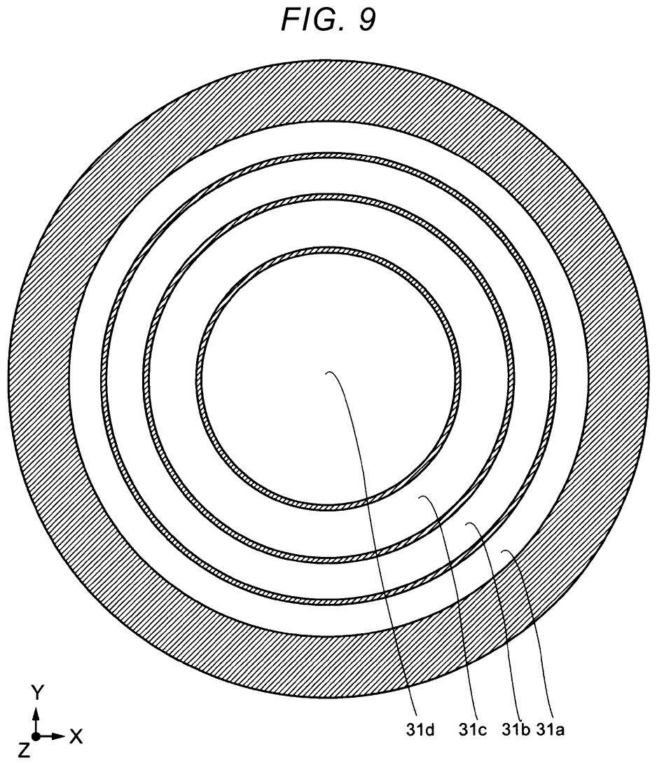

A configuration of a shower head will be described in detail with reference to FIGS. 8 and 9. FIG. 8 is an XZ sectional view illustrating a configuration of the shower head according to one embodiment. FIG. 8 is an enlarged sectional view illustrating the right half of the shower head at the location A of FIG. 2 and an overall configuration of the shower head that is the rotation body about the central axis C. FIG. 9 is an XY sectional view illustrating a configuration of the shower head according to one embodiment. FIG. 9 is a sectional view illustrating the shower head at the location E of FIG. 8.

Hollow portions 31 include hollow portions 31a, 31b, 31c, and 31d. The hollow portions 31a, 31b, and 31c have a flat cylindrical shape (doughnut shape) and are disposed concentrically about the central axis C. The hollow portion 31d has a flat columnar shape and is disposed concentrically about the central axis C. The upper and lower surfaces of the hollow portions 31a, 31b, 31c, and 31d are parallel and are disposed on the same XY surface. The hollow portion 31b is disposed inside the hollow portion 31a, the hollow portion 31c is disposed inside the hollow portion 31b, and the hollow portion 31d is disposed concentrically inside the hollow portion 31c, so that a quadruple pipe configuration is implemented. It is preferable that the hollow portions 31a, 31b, 31c, and 31d be disposed to correspond to a processing region (principal surface) of the wafer 200 placed on the substrate holding unit 210 and have substantially the same diameter as the processing region (principal surface) of the wafer 200.

In the present embodiment, volumes of the hollow portions 31a, 31b, 31c, and 31d are substantially the same. That is, areas of the hollow portions 31a, 31b, 31c, and 31d on the XY cross-sectional surfaces are substantially the same.

In a shower head 11 according to the present embodiment, since the volumes of the plurality of hollow portions 31 are substantially the same, gas supply can be controlled more accurately, and thus it is possible to improve uniformity of the gas supplied in the processing region (principal surface) of the wafer 200.

### Third Embodiment

### Shower Head

A configuration of a substrate processing apparatus according to the present embodiment is the same as the configuration of the substrate processing apparatus according to the first embodiment except for the configuration of the plurality of hollow portions and the plurality of gas ejection holes. The same description as that of the first embodiment will be omitted. Here, differences from the configuration of the substrate processing apparatus according to the first embodiment will be described.

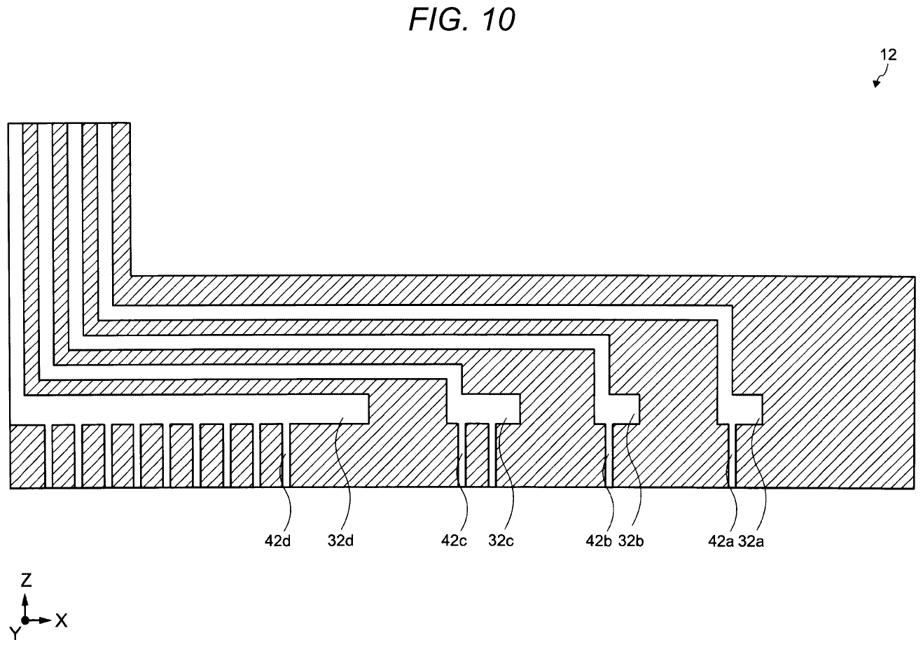

A configuration of the shower head will be described in detail with reference to FIG. 10. FIG. 10 is an XZ sectional view illustrating a configuration of the shower head according to one embodiment. FIG. 10 is an enlarged sectional view illustrating the right half of the shower head at the location A of FIG. 2 and an overall configuration of the shower head that is a rotation body about the central axis C.

Hollow portions 32 include hollow portions 32a, 32b, 32c, and 32d. The hollow portions 32a, 32b, and 32c have a flat cylindrical shape (doughnut shape) and are disposed concentrically about the central axis C. The hollow portion 32d has a flat columnar shape and is disposed concentrically about the central axis C. The upper and lower surfaces of the hollow portions 32a, 32b, 32c, and 32d are parallel and are disposed on the same XY surface. The hollow portion 32b is disposed inside the hollow portion 32a, the hollow portion 32c is disposed inside the hollow portion 32b, and the hollow portion 32d is disposed concentrically inside the hollow portion 32c, so that a quadruple pipe configuration is implemented. It is preferable that the hollow portions 32a, 32b, 32c, and 32d be disposed to correspond to a processing region (principal surface) of the wafer 200 placed on the substrate holding unit 210 and have substantially the same diameter as the processing region (principal surface) of the wafer 200.

A plurality of gas ejection holes 42 include a plurality of gas ejection holes 42a, a plurality of gas ejection holes 42b, a plurality of gas ejection holes 42c, and a plurality of gas ejection holes 42d. The plurality of gas ejection holes 42a, the plurality of gas ejection holes 42b, the plurality of gas ejection holes 42c, and the plurality of gas ejection holes 42d each eject any of various gases stored in the hollow portions 32a, 32b, 32c, and 32d to the processing region (principal surface) of the wafer 200 placed on the substrate holding unit 210. The plurality of gas ejection holes 42a communicate with the hollow portion 32a and extend in the first direction (Z direction). The plurality of gas ejection holes 42b communicate with the hollow portion 32b and extend in the first direction (Z direction). The plurality of gas ejection holes 42c communicate with the hollow portion 32c and extend in the first direction (Z direction). The plurality of gas ejection holes 42d communicate with the hollow portion 32d and extend in the first direction (Z direction).

In the present embodiment, volumes per gas ejection holes 42a, 42b, 42c, and 42d of the hollow portions 32a, 32b, 32c, and 32d are substantially the same. That is, volumes of the hollow portions 32a, 32b, 32c, and 32d depend on the disposition and number of plurality of gas ejection holes 42.

In a shower head 12 according to the present embodiment, since the volume per gas ejection hole 42 of the plurality of hollow portions 32 is substantially the same, gas supply can be controlled more accurately, and thus it is possible to improve gas replacement efficiency and uniformity of the gas inside the shower head 10.

### Fourth Embodiment

### Substrate Processing Method

Next, a substrate processing method in which the substrate processing apparatus according to the first to third embodiments is used will be described. A substrate processing method according to the present embodiment can be executed, for example, as a part of a method of manufacturing a semiconductor device. The substrate processing apparatus according to the first to third embodiments is used for a film forming process and processing treatment, but in the present embodiment, the film forming process will be described as an example thereof.

First, the wafer 200 is placed on the substrate holding unit 210 by a conveyance robot (not illustrated) and the wafer 200 is lifted up by the lifting mechanism 218. In the wafer 200, for example, circuit layers, insulating layers including metal wirings, and the like are formed.

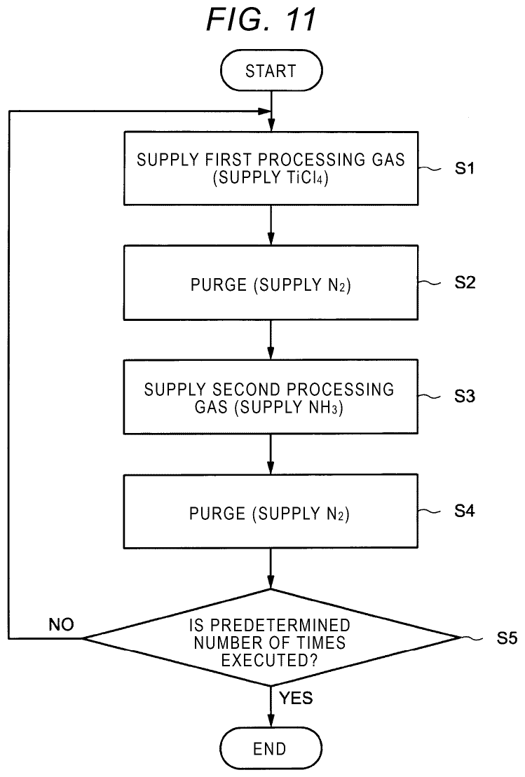

Next, a film forming process will be described in detail with reference to FIG. 11. FIG. 11 is a flowchart illustrating film forming steps according to one embodiment. A processing gas is supplied to the processing space 201 (S1). The processing gas is supplied to the processing space 201 via the pipe unit 229 and the shower head 10 from the gas supply unit. The processing gas is, for example, a material gas such as TiCl₄ that is a first processing gas.

In the substrate processing method according to the present embodiment, the valve 244 connected to each of the first pipe 229a, the second pipe 229b, the third pipe 229c, and the fourth pipe 229d is opened to supply the material gas simultaneously from the material gas supply pipe 304 to each of the first pipe 229a, the second pipe 229b, the third pipe 229c, and the fourth pipe 229d. A flow rate of the material gas flowing inside the first pipe 229a, the second pipe 229b, the third pipe 229c, and the fourth pipe 229d is adjusted by the mass flow controller 404, and the material gas is supplied to the wafer 200 inside the processing space 201 from the plurality of gas ejection holes 40a, the plurality of gas ejection holes 40b, the plurality of gas ejection holes 40c, and the plurality of gas ejection holes 40d via the slits 20 and the hollow portions 30.

Subsequently, the valves 244 are closed to stop supplying the material gas. The purge gas is supplied to the processing space 201 using a method similar to that of the material gas by opening the valves 246 and 247 of the purge gas supply pipes 306 and 307 (S2).

After the remaining gas inside the processing space 201 is removed, the valves 246 and 247 are closed and the valve 245 is opened to flow the reactive gas to the reactive gas supply pipe 305 (S3). The reactive gas is, for example, a reactive gas such as NH₃ that is a second processing gas. The reactive gas is supplied to the wafer 200 inside the processing space 201 from the plurality of gas ejection holes 40a, the plurality of gas ejection holes 40b, the plurality of gas ejection holes 40c, and the plurality of gas ejection holes 40d via each of the pipe unit 290, the slits 20, and the hollow portions 30 using a method similar to that of the material gas.

Accordingly, a film generated through reaction of the material gas and the reactive gas is formed on the wafer 200. When the material gas is TiCl₄ and the reactive gas is an NH₃ gas, a TiN (titanium nitride) on the wafer 200 is formed.

Subsequently, the valve 245 is closed to stop supplying the reactive gas. The valves 246 and 247 of the purge gas supply pipes 306 and 307 are opened to supply the purge gas to the processing space 201 using a method similar to that of the reactive gas (S4).

A film with a predetermined film thickness is formed on the wafer 200 by repeating S1 to S5 a predetermined number of times (S5). When the material gas is TiCl₄ and the reactive gas is an NH₃ gas, a TiN (titanium nitride) on the wafer 200 is formed.

In the substrate processing method according to the present embodiment, each gas is supplied to the wafer 200 via the slits 20 and the hollow portions 30 of the substrate processing apparatus described in the first to third embodiments. Accordingly, it is possible to reduce deviation in the gas inside the shower head 10 and improve uniformity of the supplied gas on the wafer. According to the present embodiment, since the shower head 10 includes the slits 20, the thickness of the shower head 10 can be thinned and gas replacement efficiency in the inside can be improved.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A substrate processing apparatus comprising:
a substrate holder configured to hold a substrate;
a shower head including a first hollow portion, a first slit coupled to the first hollow portion and extending in a first direction, a second slit coupled to the first slit and extending in a second direction intersecting the first direction and a third direction intersecting the first and second directions, a third slit coupled to the second slit and extending in the first direction, and a plurality of first gas ejection holes coupled to the first hollow portion, the shower head facing the substrate holder;
a pipe structure including a first pipe coupled to the third slit; and
a gas supplier connected to the first pipe and configured to supply a gas to the substrate from the plurality of first gas ejection holes.

2. The substrate processing apparatus according to claim 1, wherein the first, second, and third slits have a cylindrical shape and are disposed concentrically at the first hollow portion.

3. The substrate processing apparatus according to claim 1,
wherein the shower head further includes a second hollow portion separated concentrically from the first hollow portion, a fourth slit coupled to the second hollow portion and extending in the first direction, a fifth slit coupled to the fourth slit and extending in the second and third directions, a sixth slit coupled to the fifth slit and extending in the first direction, and a plurality of second gas ejection holes coupled to the second hollow portion,
wherein the pipe structure further includes a second pipe coupled to the sixth slit, and
wherein the gas supplier is connected to the second pipe and configured to supply a gas from the plurality of second gas ejection holes to the substrate.

4. The substrate processing apparatus according to claim 3, wherein the fourth, fifth, and sixth slits have a cylindrical shape and are disposed concentrically at the first hollow portion.

5. The substrate processing apparatus according to claim 3, wherein the second and fifth slits are disposed in parallel with each other.

6. The substrate processing apparatus according to claim 3, wherein the first and second hollow portions are disposed concentrically.

7. The substrate processing apparatus according to claim 3, wherein a volume of the first hollow portion is equal to a volume of the second hollow portion.

8. The substrate processing apparatus according to claim 3, wherein a volume of the first hollow portion per the plurality of first gas ejection holes is equal to a volume of the second hollow portion per the plurality of second gas ejection holes.

9. The substrate processing apparatus according to claim 3,
wherein the shower head further includes a third hollow portion separated concentrically from the first and second hollow portions, a seventh slit coupled to the third hollow portion and extending in the first direction, and a plurality of third gas ejection holes coupled to the third hollow portion,
wherein the pipe structure further includes a third pipe coupled to the seventh slit, and
wherein the gas supplier is connected to the third pipe and configured to supply a gas to the substrate from the plurality of third gas ejection holes.

10. The substrate processing apparatus according to claim 9, wherein the first and seventh slits are disposed concentrically.

11. The substrate processing apparatus according to claim 9, wherein the first and third hollow portions are disposed concentrically.

12. The substrate processing apparatus according to claim 9, wherein a volume of the first hollow portion is equal to a volume of the third hollow portion.

13. The substrate processing apparatus according to claim 9, wherein a volume of the first hollow portion per the plurality of first gas ejection holes is equal to a volume of the third hollow portion per the plurality of third gas ejection holes.

14. A substrate processing method comprising processing a substrate using the substrate processing apparatus according to claim 1.

15. A substrate processing method comprising processing a substrate using the substrate processing apparatus according to claim 2.
